(19) United States
(12) Patent Application Publication
(10) Pub. No.: US 2014/0231630 A1
(43) Pub. Date: Aug. 21, 2014

(54) METHOD AND APPARATUS FOR IMAGE SENSOR CALIBRATION

(71) Applicant: STMicroelectronics (Research & Development) Limited, Marlow (GB)

(72) Inventors: Bruce Rae, Edinburgh (GB); John Kevin Moore, Edinburgh (GB)

(73) Assignee: STMicroelectronics (Research & Development) Limited, Marlow (GB)

(21) Appl. No.: 14/180,819

(22) Filed: Feb. 14, 2014

(30) Foreign Application Priority Data
Feb. 18, 2013 (GB) 1302787.5

(51) Int. Cl. H01L 31/09

(52) U.S. Cl. CPC H01L 31/09
USPC 250/214.1

(57) ABSTRACT

A photon sensitive device is provided with a voltage. A controller is configured to control a voltage source so as to cause at least one calibration voltage to be applied to the photon sensitive device in a calibration mode in order to determine the voltage to be provided by the voltage source in a normal mode of operation.

### PRIORITY CLAIM

This application claims priority from Great Britain Application for Patent No. 1302787.5 filed Feb. 18, 2013, the disclosure of which is incorporated by reference.

### TECHNICAL FIELD

This disclosure relates to a method and apparatus and in particular, but not exclusively to, an apparatus comprising at least one photosensitive device and a method associated therewith.

### BACKGROUND

A single photon avalanche detector (SPAD) is based on a p-n junction device biased beyond its breakdown region. A high reverse bias voltage generates a sufficiently large electric field such that a single charge carrier introduced into a depletion layer of the p-n junction device can cause a self-sustaining avalanche. This charge carrier may be released by the impact of a photon (impact ionization). The SPAD may be quenched, allowing the device to be reset to detect further photons.

### SUMMARY

According to a first aspect, there is provided an apparatus comprising at least one photon sensitive device, the or each of said photon sensitive devices being provided with a voltage; and a controller configured to control a voltage source, said controller configured to cause said voltage source to apply at least one calibration voltage to the or each photon sensitive device in a calibration mode to determine a voltage to be provided by the voltage source in a normal mode of operation.

According to another aspect, there is provided a method comprising controlling a voltage source to apply at least one calibration voltage to at least one photon sensitive device in a calibration mode to determine a voltage to be provided by the voltage source in a normal mode of operation.

### BRIEF DESCRIPTION OF THE DRAWINGS

Reference will now be made, by way of example only, to the accompanying drawings in which:

FIG. 1 is a diagram of a SPAD with a quench and readout circuit;

FIG. 2 shows a schematic diagram of an embodiment;

FIG. 3 shows a method of an embodiment;

FIG. 4 shows schematically SPAD bias voltages and operating conditions:

FIGS. 5 and 6 illustrate the operation of the arrangement of FIG. 13 in more detail;

FIGS. 7A to F are timing diagrams illustrating the operation of the arrangement of FIG. 13;

FIGS. 8A to 8E, 9A to 9E, and 10A to 10F are timing diagrams illustrating the operation of the device of shown in FIG. 11;

FIG. 11 illustrates a device for calculating the distance to an object based on the signals obtained from the arrangement of FIG. 13;

FIG. 12 shows a block diagram of an embodiment;

FIG. 13 illustrates part of the embodiment of FIG. 12 in more detail; and

FIG. 14 shows a device having a SPAD arrangement

### DETAILED DESCRIPTION OF THE DRAWINGS

Single-photon avalanche diodes, or “SPADs”, are also called Geiger mode avalanche photo diodes GAPD. These devices have a reverse biased p-n junction in which a photo-generated carrier can trigger an avalanche current due to an impact ion mechanism. SPADs may be designed to operate with a reverse bias voltage well above the breakdown voltage.

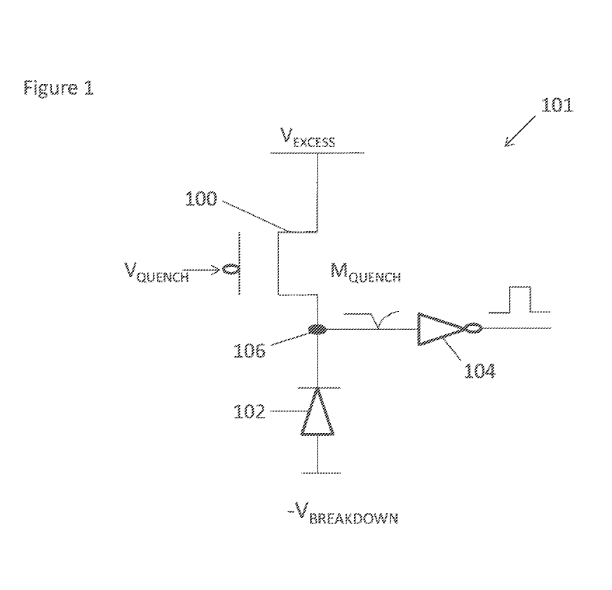

FIG. 1 schematically shows a single photon avalanche diode (SPAD) 101. The SPAD 101 has a reverse biased p-n junction 102. The reverse biased p-n junction 102 has a high reverse bias voltage (−V_{BREAKDOWN}). With this reverse bias voltage, a relatively high electric field is generated such that a single charge carrier injected into the depletion layer triggers a self-sustaining avalanche via impact ionization. In other words, a photon impacting on the reverse biased p-n junction device 102 releases a single charge which triggers a chain reaction releasing a large number of electrons leading to a large current.

To reset the device 102, the current flow is quenched. Without quenching, the p-n junction device 102 may be permanently damaged.

Different types of quenching are known. For example, passive or active quenching may be used. Passive quenching may, for example, use a resistor in series with the SPAD. The avalanche current is effectively quenched as a voltage drop is developed across a relatively high value resistance of the resistor. Alternatively, active quenching may be used.

FIG. 1 shows an example where passive quenching is used. A p-type MOSFET (metal-oxide-semiconductor field-effect transistor) 100 is provided in series with the p-n junction device 102 and is connected between the more positive voltage, V_{EXCESS} and the reverse biased p-n junction device 102. A quenching voltage V_{QUENCH} is applied to the gate of the MOSFET 100. Effectively the MOSFET 100 acts as a relatively high resistance resistor.

The voltage waveform at the node 106 between the MOSFET 100 and the p-n junction device 102 can be seen schematically in FIG. 1. Initially, the output of the node 106 is at a relatively high voltage. When the photon impacts on the p-n device 102, this causes a relatively large current to flow rapidly which causes the voltage on node 106 to drop rapidly. As the quenching voltage is applied, the voltage at node 106 rises back up to the initial voltage value. The voltage waveform at node 106 is passed through an inverter 104 to give a square waveform with the low levels of the wave representing the state prior to the impact of the photon on the P-N device and after quenching, and the high level representing the impact of a photon. The output of the inverter 104 can be provided to detection circuitry to be processed. For example, the output of the inverter 104 can be input to a counter which counts every time the output of the inverter goes high.

It should be appreciated that the SPAD shown in FIG. 1 and the quenching arrangement is by way of example only and other structures may alternatively be used. For example, active quenching may be used. Other passive quenching arrangements may be used in embodiments.

In some embodiments, a positive breakdown voltage may be used. In that case, the SPAD would be connected to the more positive voltage with a quenching arrangement between the SPAD and the more negative voltage. The quenching arrangement may be for example an N type transistor.

It should be appreciated that the inverter may be omitted in some embodiments. Any suitable detection circuitry may additionally or alternatively be used.

In some embodiments, an array of SPADs is used. However it should be appreciated that some embodiments may be used with a single SPAD.

A breakdown voltage is required to place the avalanche diodes in the Geiger region of operation and cause the p-n device to operate as a SPAD. The breakdown voltage is controlled by the voltage differential across the p-n device rather than the absolute voltage values on either side of the reverse biased p-n junction device.

The breakdown voltage of the diode may be sensitive to one or more of the following factors: process variation; the SPAD design; variation in the components over time; and temperature variation.

In a SPAD provided on a chip, on a die, or as part of a chip set, this voltage provided to the SPAD may be provided by a voltage source on the same chip or die, or on another chip of the chip set or another die (packaged for example with the die having the SPAD). Alternatively, the voltage supply may be an external supply. If a SPAD is reverse biased with a voltage differential (controlled by the voltage supply) which is either too low or too high, the p-n device will not operate as a single photon sensitive avalanche diode.

In order to ensure correct operation of the SPAD taking into account one or more of the above factors, the voltage used should be calibrated. Various different factors may be considered in determining an optimum breakdown voltage for a particular SPAD or use of that SPAD. For example, in some scenarios, the optimum bias voltage may be considered to be the voltage at which the SPAD achieves its maximum count rate or best timing performance. Alternatively, in some embodiments, the optimum voltage may be considered to be the middle of the region of operation which may provide a compromise between two or more of count rate, timing performance and dark count rate. The SPAD may be sensitive to thermally generated carriers which fire the avalanche process. The average number of counts per second when the SPAD is in complete darkness is referred to as the dark count rate and is a parameter which is used in defining the detector noise. The reciprocal of the dark count rate defines the average time that the SPAD will remain biased above breakdown before being triggered by an undesired thermal process. Usually, a SPAD is designed so as to remain biased above breakdown for a sufficiently long time in order to work correctly as a single photon detector.)

Some embodiments may allow the single photon avalanche diode to operate over a wide range of temperature conditions and/or to accommodate process variations and/or design variations.

In some embodiments, recalibration of the breakdown voltage may be carried out relatively often.

It should be appreciated that the voltage calibration may be performed when the device is first used and/or each time the device is used. Where the calibration is performed each time the device is used, the calibration may be repeated carried out during the use of that device.

The previous proposals for SPAD design have failed to recognize the need to adjust the bias voltage. The inventors have recognized that, for example, as temperature conditions change, the breakdown voltage of the SPAD diode may drift. If the voltage provided by for example an on chip voltage source is fixed, then the breakdown voltage may be insufficient or too high for the SPAD to operate in the Geiger mode and have the effect as described previously.

In some embodiments, a SPAD arrangement may be required to operate over a wide range of temperature conditions. In some SPADs there may be an alteration in breakdown voltage of around 0.1V per 10 degrees centigrade. This may be significant in that in some cases the operation region of a SPAD may have an extent of 1 to 2 V between the lowest usable voltage and the highest usable voltage.

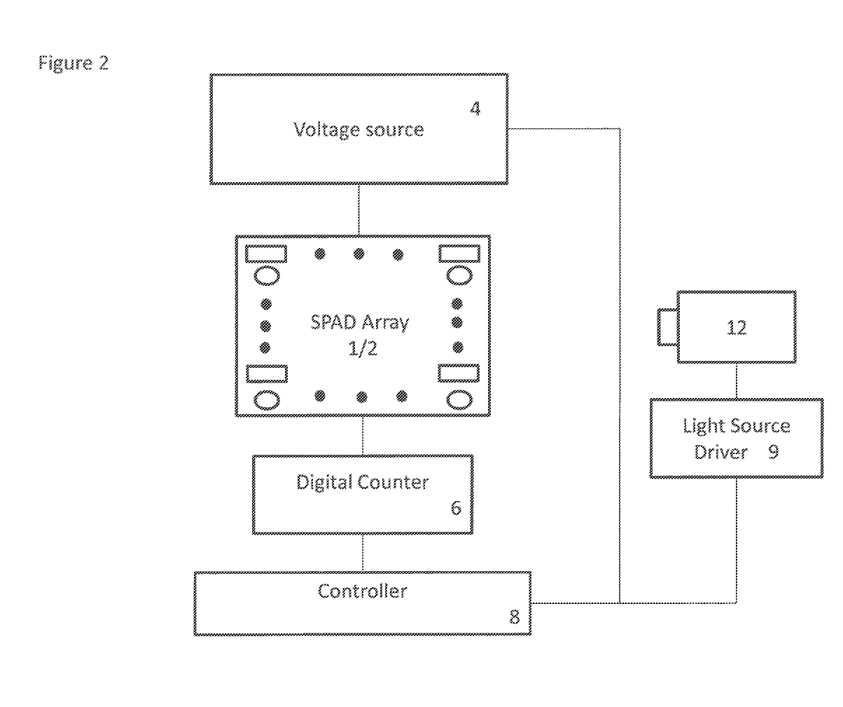

Reference is made to FIG. 2 which shows one embodiment. The arrangement comprises a voltage source 4. This voltage source may provide for example V_{EXCESS}, as shown in FIG. 1. This voltage source may be an on chip voltage source. Where the voltage source is an on chip voltage source, that voltage source may be a charge pump. In some embodiments, as the SPAD may require a relatively high voltage (compared to the usual chip voltages). The SPAD voltage supply can be controlled in any suitable way, for example by means of an on chip charge pump, a regulator or an external power supply controllable by an output from the chip. It should be appreciated that in alternative embodiments, the voltage source may be an external to the chip and again may take any suitable format.

The voltage source 4 is configured to control the voltage applied to the SPAD array 2. In one embodiment, the voltage source may be used to control V_{EXCESS} whilst −V_{BREAKDOWN} is kept constant. Alternatively, V_{EXCESS} may be kept constant and −V_{BREAKDOWN} may be controlled by the voltage source. In some embodiments, both −V_{BREAKDOWN} and V_{EXCESS} may be varied.

In the following example, the voltage source will control V_{EXCESS}. The voltage source 4 provides the voltage which is used in each SPAD of the SPAD array 1/2. Each SPAD may be as shown in FIG. 1. The output of each SPAD is provided to a digital counter 6. In one embodiment, the digital counters 6 will count each time the output of the inverter 104 goes high, as shown in FIG. 1. The output of the digital counter 6 is input to a controller 8. The controller may take any suitable form and may be implemented by hardware, software and/or a combination of the two. In some embodiments, the controller may comprise a firmware controller. The output of the controller 8 is used to provide an input to the voltage source 4. The input provided by the controller 8 controls the voltage which is provided by the voltage source 4.

The controller 8 is configured to put the arrangement of FIG. 2 into a calibration mode. When the arrangement is in a calibration mode, a control signal is provided by the controller 8 to a light source driver 9. In turn, the light source driver will control a light source 12, switching it on or off. Where the device is part of a chip or the like, the light source may be in the same package or a different package.

The controller is configured to cause the voltage source to apply one or more different voltages to the array.

In some embodiments, the controller may be configured to control the voltage source to cycle through a plurality of output voltage values. The counts associated with each of the output calibration voltages are stored by the controller 8. Based on the results of the calibration, i.e. counts, the controller will select the appropriate voltage to be provided by the voltage source during the normal operation of the SPAD array.

In some embodiments, the SPAD array used for calibration may be a reference SPAD array or may be part or the entire SPAD array used for detection. If the SPAD array used for calibration is a reference array, then the reference array may be shielded from ambient light in for example a closed housing. If the SPAD array used for calibration is also used in normal operation, then the SPAD array may be shielded during the calibration mode.

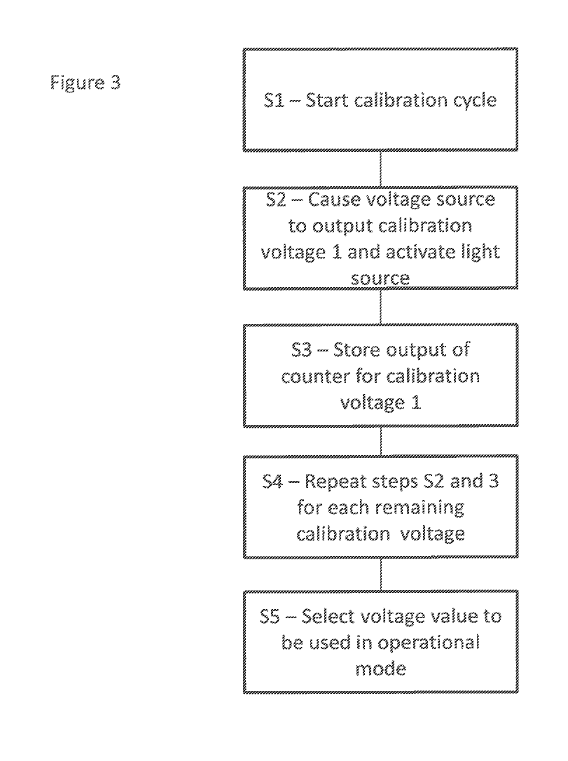

Reference is made to FIG. 3 which shows a method of an embodiment.

In step S1, a calibration cycle is started. The starting of the calibration cycle may be controlled by the controller.

In step S2, the voltage source is controlled to output a first calibration voltage and the light source is activated or switched on. The voltage source may be controlled by the controller.

In step S3, the output of the counter for that first calibration voltage is stored by the controller in a memory accessible by the controller. The memory may be part of the controller or separate from the controller.

In step S4, steps S2 and S3 are repeated for each the remaining calibration voltages. The light source may be continually activated or may be activated each time a new voltage is applied.

In step S5, the results of the counts are used by the controller to select the voltage value to be provided by the voltage source in an operational mode.

In some embodiments, the calibration cycle is carried out at defined time intervals. In some embodiments, the normal operation mode may be interspersed with calibration mode periods. In some embodiments, depending on the use of the SPAD arrangement, calibration may be performed when the SPAD is not required to be in a normal mode of operation.

In alternative embodiments, the calibration cycle is controlled to take place alternatively or additionally in response to the determination of one or more conditions. For example, in some embodiments, one or more sensors may be provided and the output of those sensors may be used to control when a calibration cycle is performed. For example, in some embodiments, a temperature sensor may be used and this may for example be used to control a calibration cycle. The absolute temperature may be used in order to control when a calibration cycle is used. Alternatively or additionally, when the temperature has changed by a predetermined amount, then a calibration cycle may be performed.

In some embodiments, the counter 6 will collect all of the values from all of the SPADs of the array during calibration and use this information to determine an average value across the array.

In other embodiments, the counter will collect values from one or only some of the SPADs of the array.

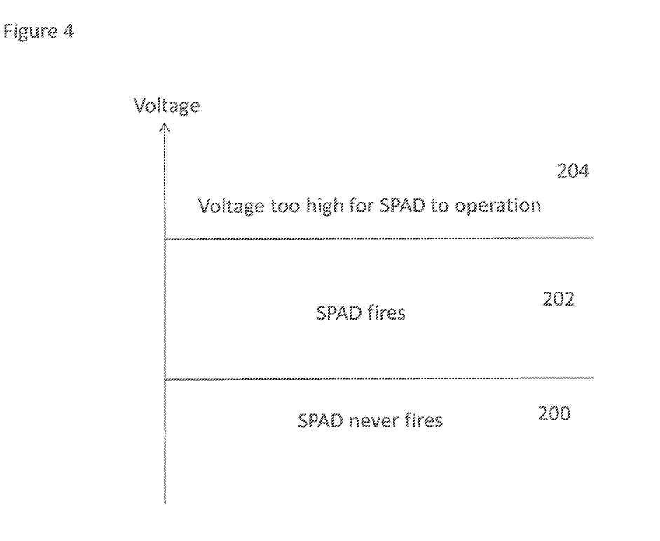

Reference is made to FIG. 4 which shows a summary of SPAD bias voltage and operating conditions. The voltage of the y-axis of FIG. 4 represents a magnitude value rather than an absolute value. If the breakdown voltage i.e. the voltage differential across the SPAD is insufficient, the SPAD never fires. This is referenced 200.

As the voltage increases, the SPAD enters its normal operating range. This is referenced 202. In this region the energy release by the impact of a photon triggers the avalanche effect.

As the voltage further increases, the voltage is too high for the SPAD to operate as required. This is region 204. In practice the divisions between the regions may not be as clearly defined as shown in FIG. 4. Thus in some embodiments, it may be desirable for the SPAD voltage to be such that that the SPAD operates well within the region 202 and not close to the border regions adjacent either region 200 or region 204. Region 202 may be considered to be the region in which the SPAD is most photo responsive.

Different embodiments may use different options for selecting the most appropriate voltage. It should be appreciated that in some embodiments, more than one voltage setting option may be available. This may be selected by the controller. This may be for example dependent on a use, environmental condition (e.g. temperature) or any other suitable parameter.

The desired bias voltage may be one at which the SPADs achieve a maximum count rate, best time performance or a voltage which provides a compromise between count rate, timing performance and/or dark count rate.

In one embodiment, the voltage setting that provides the maximum SPAD current rate can be selected. The voltage setting can be increased from a low voltage, i.e. below the breakdown of the voltage of the SPAD) until the breakdown voltage of the SPAD is established. The breakdown voltage of the SPAD 80 is determined when an appropriate count is detected by the digital counter. A fixed voltage offset or an increase can be applied so that that it is known how far beyond the breakdown voltage the bias has been set.

The voltage offset may be controlled by the controller and different offsets may be available.

Alternatively, the differential voltage can be set higher than the maximum SPAD bias voltage, placing the SPAD in permanent breakdown. The bias voltage can then be reduced until the SPAD begins to operate. The bias voltage can then be reduced by a fixed amount in order to place the SPAD at a bias current which is fixed with respect to the maximum breakdown voltage.

In an alternative embodiment, the controller may select a voltage. If the SPAD operates as required, then that voltage is used and if not another voltage is selected.

In another approach, if the SPAD operates as required at the selected voltage, a check is made to see if the SPAD operates with an offset on one or other or both sides of that selected voltage. If the SPAD does not work as required with the offset for example on either side, then the new SPAD voltage may be selected using the performance with respect the offset voltages as a guide as to whether to increase or decrease the selected voltage.

Alternatively or additionally some embodiments may use a binary search or half interval type technique. For example, in each step, an algorithm may compare the count associated with a calibration voltage value being used with a desired count value. It the values match or are within a given range, then the calibration voltage is determined to be a candidate voltage value. Some further calibration voltages may be used to determine if the calibration voltage is well within the desired operating range, for example by using on or more offsets.

If the count values do not give a desired result, then depending on the count value, a higher or lower calibration voltage may be used in a next calibration cycle. This is repeated until a calibration voltage gives the required performance.

The SPAD array used in embodiments may have any suitable application. For example, some embodiments may be used in ranging applications.

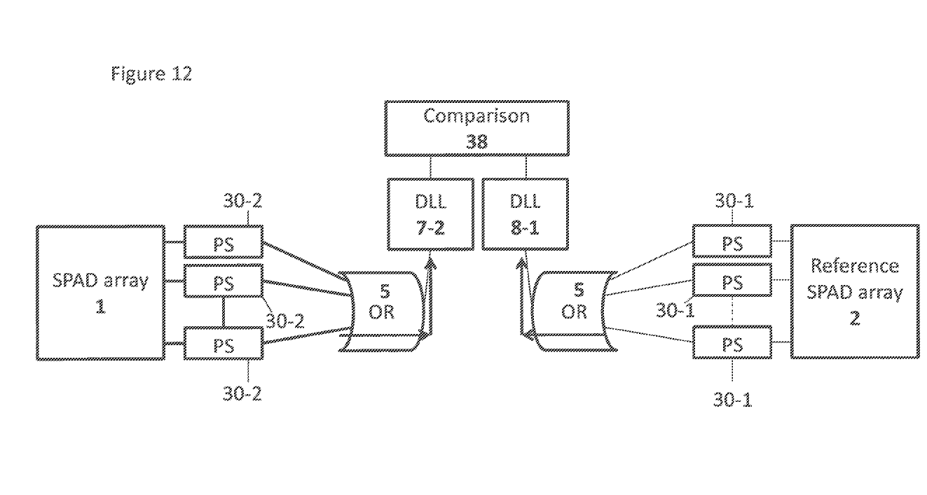

Reference is now made to FIG. 12 which schematically shows an overview of an embodiment. The arrangement comprises a first SPAD array 1 and a reference SPAD array 2. Each SPAD array comprises a plurality of SPAD devices.

The SPAD array 1 provides a plurality of outputs. By way of example, each SPAD of the array may provide an output. The respective outputs of the first SPAD array 1 are provided to respective circuitry 30-2 which are arranged to shape the output of the respective SPAD. This circuitry will be referred to as pulse shaping circuitry. Each output may thus have its own pulse shaping circuitry.

Likewise, the respective row outputs of the reference SPAD array 2 are provided to respective pulse shaping circuitry 30-1. The outputs of each of the pulse shaping circuitry 30-2 associated with the first SPAD array 1 are input to an OR tree 5. Likewise, the output of each of the pulse shaping circuitry 30-1 associated with the reference SPAD array 2 are provided to a second OR tree 5. The output of the first OR tree 5 is provided to a delay lock loop DLL 8-2 whilst the output of the second OR tree 6 is provided to a second DLL 8-1.

The outputs of the two DLLs are compared by a comparator arrangement 38 to determine a distance of an object, as will be described in more detail later.

In this example a pulse shaping circuitry is provided for each SPAD of the respective arrays but in other embodiment, a different relationship between the pulse shaping circuitry and output of the array may be supported.

Some embodiments may obtain ranging information based on the average phase shift between signals provided by two SPADs or SPAD arrays (one a reference SPAD and the other a measurement SPAD). This will be described in more detail later. This may for example be used in ranging applications in which the distance of an object from the device is determined.

In some embodiments, only one of the two arrays may be calibrated. For example this may be the reference array. In other embodiments both of the arrays may be calibrated.

Some embodiments may be integrated in a device enabling the accurate determination of the phase shift between signals.

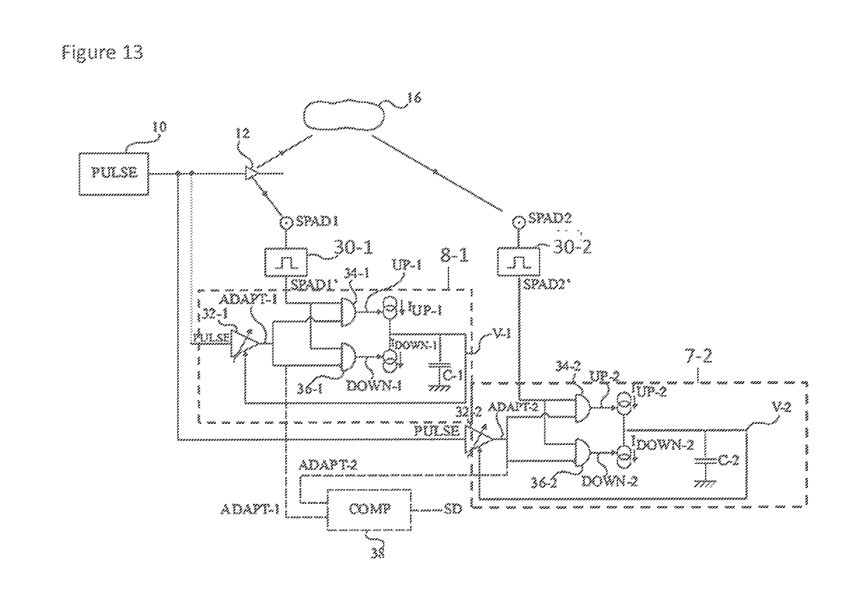

FIG. 13 shows in more detail some of the circuitry which may be associated with the arrangement of FIG. 12. FIG. 13 illustrates shows a single SPAD, SPAD 2 of the first SPAD array 1 and a single SPAD, SPAD 1 of the reference array 2, for simplicity. It should be appreciated that the OR trees of FIG. 3 are not shown.

The device comprises an electric generator 10 (“PULSE”) having a periodic square output powering the light source 12. The electronic generator may be part of the controller 9 of FIG. 2. The first single-photon avalanche diode, SPAD1, of the reference array is placed very close to light source 12 and thus may almost instantaneously receives the signal transmitted by light source 12.

A second single-photon avalanche diode, SPAD2, is placed to receive the light signal emitted by source, 12, after reflection on an object 16. A mask system between the two diodes may for example be used so that diode SPAD2 does not receive the light directly emitted by light source 12 and that diode SPAD1 is triggered predominantly by light reflected inside the device.

The use of sensor SPAD1 very close to light source 12 provides improved reference information with respect to the reference information directly provided by generator 10. Indeed, since the signal coming out of sensor SPAD1 is of the same type as that coming out of sensor SPAD2, other conditions, such as the ambient light, may have the same influence on both signals. The comparison between these signals may thus more reliable than the comparison between the signal output by sensor SPAD2 and the signal output by generator 10. However it should be appreciated that in some embodiments, the reference SPAD may be omitted.

The diodes SPAD1 and SPAD2 generate pulses on reception of the light beams that they receive. In the following description, since the circuits associated with diodes SPAD1 and SPAD2 are the same, an extension “-1” will be used to designate circuit elements associated with diode SPAD1, and an extension “-2” will be used to designate elements associated with diode SPAD2.

The electronic circuit associated with the signal generated by diode SPAD1 will now be described, the circuit associated with diode SPAD2 being the same.

The signal emitted by diode SPAD1 crosses a pulse shaping circuit 30-1 enabling the reshaping of the pulses generated by diode SPAD1. More specifically, circuit 30-1 delivers a signal SPAD1′ exhibiting pulses having their beginning coinciding with the beginning of pulses of the signal SPAD1, but of constant duration.

The signal coming out of generator 10 (“PULSE”) is coupled to the input of the DLL 8-1 and in particular to the input of a phase shifter circuit 32-1 of variable phase shift, having its value varying according to a voltage V-1 applied thereto as a control. The output of phase shifter 32-1, called ADAPT-1, is thus phase-shifted with respect to the signal generated by the generator 10 and is the output of the DLL 8-1. An AND gate, 34-1, receives the signal SPAD1′ and the signal ADAPT-1 on its two non-inverting inputs. A second AND gate, 36-1, receives the signal SPAD1′ on a first non-inverting input and the signal ADAPT-1 on a second inverting input. The output of gate 34-1 is called UP-1 and the output of gate 36-1 is called DOWN-1. The signals UP-1 and DOWN-1 respectively control the activation of current sources IUP-1 and IDOWN-1, which are respectively placed between a power supply source (not shown) and a second terminal of a capacitor C-1 and the first terminal of capacitor C-1 and the ground. Capacitor C-1 is placed between the junction point of the current sources and ground. The voltage across capacitor C-1 corresponds to the signal V-1 for controlling phase shifter 32-1 of variable phase shift. This circuitry is the DLL 8-1

The signal ADAPT-1 of the circuit associated with diode SPAD1 and the signal ADAPT-2 of the circuit associated with diode SPAD2 are coupled to the input of a comparison system 38 (COMP) which provides a signal SD which is dependent on the phase shift between the signals ADAPT-1 and ADAPT-2.

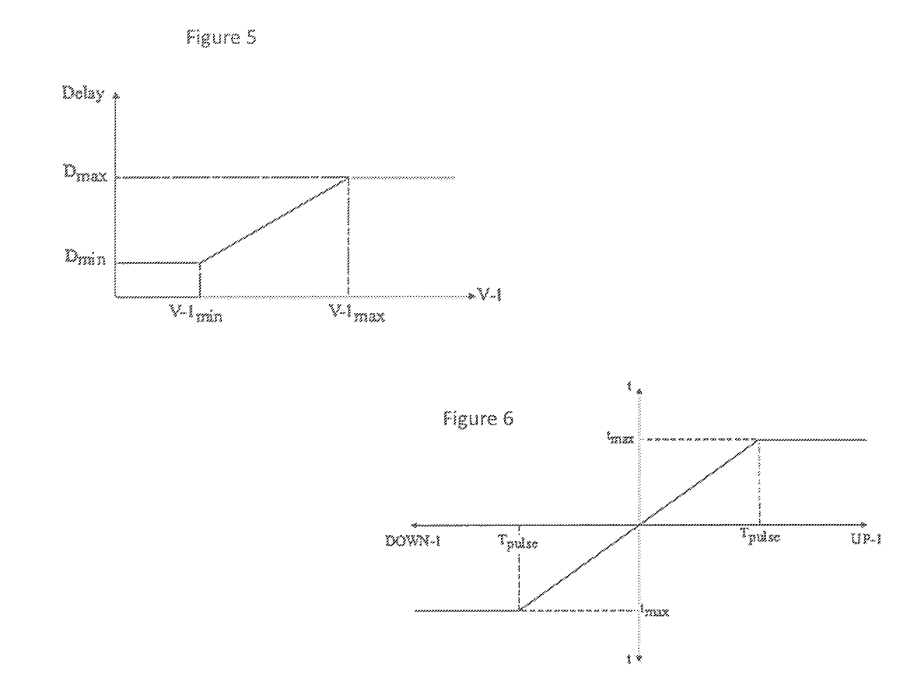

FIG. 5 is a graph illustrating the operation of phase shifter 32-1. This curve illustrates the phase shift signal DELAY between the output signal ADAPT-1 and the input signal PULSE, according to the value of a control voltage V-1. As illustrated in this graph, the phase shift is constant and equal to a duration Dmin for a voltage V-1 smaller than a voltage V-1min and equal to a value Dmax when the voltage V-1 is greater than a voltage V-1max. Between voltages V-1min and V-1max, the phase shift signal DELAY is linear with a positive slope between values Dmin and Dmax. As an example, a minimum phase shift Dmin may be equal to zero and a maximum phase shift Dmax may be equal to a period of the output signal of generator 10. Other configurations may be used, for example, if it is known that the distance to the object to be detected implies a delay ranging between predetermined values.

FIG. 6 is a graph illustrating the operation of the system comprising current sources IUP-1 and IDOWN-1, controlled by the signals UP-1 and DOWN-1. The graph of FIG. 6 illustrates the activation time of current sources IUP-1 and IDOWN-1 according to the duration of the signals UP-1 and DOWN-1. A threshold value TPULSE defines a minimum time limit for which the duration of the signals UP-1 and DOWN-1 has no influence. The aim is, when current source IUP-1 is activated, for capacitor C-1 to charge, which increases voltage V-1 and, when current source IDOWN-1 is activated, for capacitor C-1 to discharge, which decreases voltage V-1.

When the time in the high state of the signal UP-1 exceeds duration TPULSE, the current source IUP-1 is activated for a predetermined duration tmax. When the signal DOWN-1 is in a high state for a duration greater than a duration TPULSE, the current source IDOWN-1 is activated for the duration tmax, and capacitor C-1 discharges by a predetermined value. If the duration of the control signals UP-1 and DOWN-1 is shorter than the duration of TPULSE, the activation duration of sources IUP-1 and IDOWN-1 is proportional to this duration. Thus, during a cycle, if the signal UP-1 and the signal DOWN-1 are alternately in the high state, the amount of current injected into capacitor C-1 may be zero.

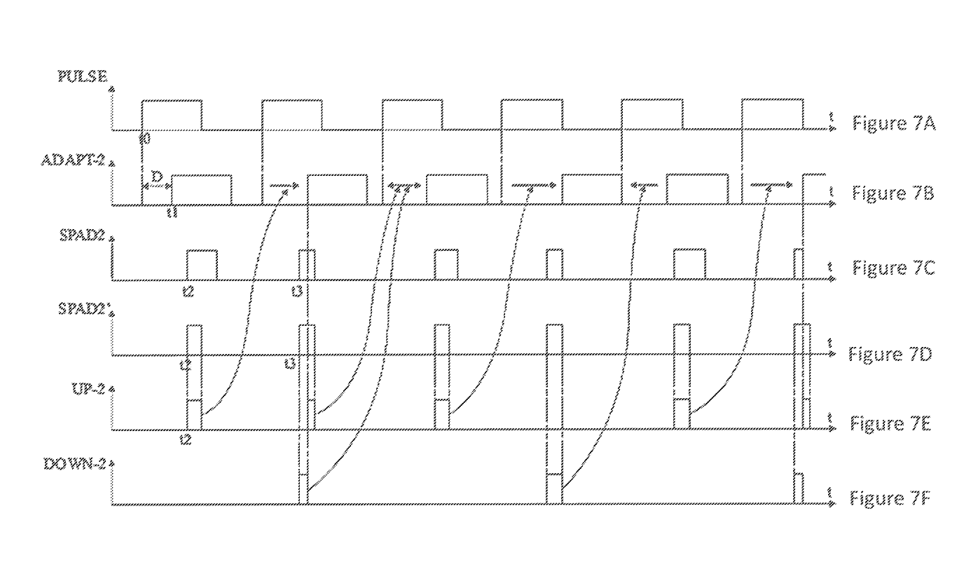

FIGS. 7A to 7F are timing diagrams illustrating the operation of the device of FIGS. 3 and 4, for the diode SPAD2. More specifically, FIG. 7A illustrates the signal PULSE at the output of generator 10 or of light source 12, FIG. 7B illustrates the signal ADAPT-2, FIG. 7C illustrates the signal transmitted by diode SPAD2, FIG. 7D illustrates the signal SPAD2′, FIG. 7E illustrates the signal UP-2, and FIG. 7F illustrates the signal DOWN-2.

At a time t0, the signal PULSE switches from a low state to a high state. An arbitrary initial delay between the signal PULSE and the signal ADAPT-2 by one quarter of a period (D) is here considered. It should be noted that the initial delay of the signal ADAPT-2 may be zero, randomly generated, or set to a predetermined value.

At a time t1, shifted by a duration D from time t0, the signal ADAPT-2 switches to the high state. At a time t2, the diode SPAD2 generates a pulse associated with the reception of a light photon reflected by the object. The signal SPAD2 is reshaped by circuit 30-2 to obtain a signal SPAD2′ starting at time t2 but having a same duration over the different periods.

While the signal SPAD2′ is in the high state, the signal ADAPT-2 also is in the high state, which causes a switching of the signal UP-2 to the high state for the duration of the pulse of the signal SPAD2′. As illustrated by an arrow, the switching to the high state of the signal UP-2 increases the phase shift between the signal PULSE and the signal ADAPT-2 at the next period.

During the next cycle, diode SPAD2 emits a pulse at a time t3. In the shown example, a first half of the pulse reshaped by circuit 30-2 (SPAD2′) occurs while the signal ADAPT-2 is the low state, and the second half of the pulse occurs while the signal ADAPT-2 is in the high state. This causes the successive switching to the high state of the signal DOWN-2 and of the signal UP-2. Current sources IUP-2 and IDOWN-2 are thus alternately activated. Since the current injections of these two sources mutually cancel, the phase shift between the signals PULSE and ADAPT-2 does not vary during the third period.

As illustrated in the timing diagrams of FIGS. 7A to 7F, the method described here above carries on for a large number of cycles. The adjustment of the phase shift between the signals ADAPT-2 and PULSE is performed by stages of low amplitude, which may minimize the influence of pulses which would occur far from the point of maximum power reception by diode SPAD2.

The circuit of FIG. 4 thus may obtain, after a large number of adjustment cycles, a the signal ADAPT-1 which is phase-shifted from the signal PULSE and having the beginning of a period coinciding with the average time of occurrence of the pulses on diode SPAD1 and a signal ADAPT-2 which is phase-shifted from the signal PULSE and having the beginning of a period coinciding with the average time of occurrence of the pulses on diode SPAD2. “ADLL” (Analog Delay Locked Loop) will be used hereinafter to designate a loop formed of a phase shifter 32, of gates 34 and 36, of current sources IUP and DOWN, and of a capacitor C, providing the signal ADAPT.

Advantageously, the use of two ADLLs may avoid a phase shift that may occur between the signal of generator 10 and the signal of sensor SPAD2 due to delays inherent with driving the light source. Further, the obtaining of the signals ADAPT-1 and ADAPT-2 after a large number of adaptation cycles may limit the device sensitivity to the waveform of the light emitted by the generator.

The method provided herein provides two phases for each distance determination. A first phase comprises obtaining periodic phase-shifted signals ADAPT-1 and ADAPT-2, as described here above by means of the two ADLLs. As an example, the adjustment may be performed over a number of cycles varying between 100,000 and 10 million. In some embodiments, if the aim is to obtain a proper adjustment within a delay ranging between 1 and 10 ms, the adjustment may be performed over approximately one million cycles, if the signal PULSE has a period of the order of one nanosecond. A second phase comprises blocking the phase adjustment and working on the signals ADAPT-1 and ADAPT-2 having a phase shift which no longer varies, and determining the duration of this phase shift.

However, the measurement of this phase shift is not immediate. Indeed, due to the short distances which are desired to be detected, this phase shift may be very small. It may be necessary to provide a device providing distance information based on the signals ADAPT-1 and ADAPT-2.

Many variations of the device and of the method described here above may be provided. A step prior to the phase shift adjustment may be provided, during which the voltage across capacitors C-1 and C-2 is initialized to a predetermined value, for example, half its maximum value. This may enable a faster adjustment towards appropriate phase shifts of the signals ADAPT-1 and ADAPT-2. It may also be provided to set the voltage across capacitors C-1 and C-2 to a different value if information relative to the distance is known. For example, the initial adjustment of the voltage across the capacitors may be performed by means of a comparator receiving the signal ADAPT-1 or ADAPT-2 on an input and a reference voltage on another input, the output of this comparator activating current sources IUP-1, IUP-2, IDOWN-1 or IDOWN-2.

A step preceding the phase shift adjustment may also be provided, during which a phase shift in the idle state, that is, with no light wave reception, is measured between voltage ADAPT-1 and ADAPT-2. This phase shift will then be subtracted from the measurements if necessary.

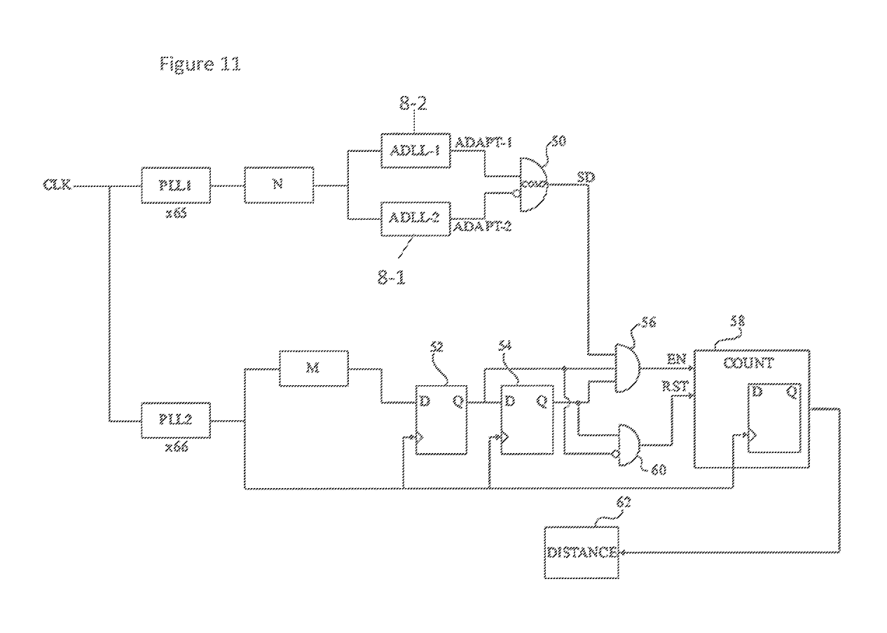

FIG. 11 illustrates a device showing using one method to for determining of the duration of the phase shift between the signals ADAPT-1 and ADAPT-2, and thus the distance to object 16. The circuit of FIG. 11 schematically shows the elements of the circuit of FIG. 4: two blocks ADLL-1 and ADLL-2 correspond to the blocks 8-1 and 8-2 respectively.

The circuit of FIG. 11 comprises a main input receiving a clock signal CLK. A first branch of the circuit, receiving clock signal CLK as an input, comprises a first phase-locked loop PLL1 and a circuit for dividing the frequency by a factor N. Phase-locked loop PLL1 increases the frequency of the output signal by a factor nPLL1, and the dividing circuit divides this frequency to obtain a frequency lower than the maximum avalanche triggering frequency of diodes SPAD.

The output signal of divider N corresponds to the signal PULSE of the circuit of FIG. 4 for circuits ADLL1 and ADLL2. The signals ADAPT-1 and ADAPT-2, once adjusted and set, are coupled to the input of an AND gate 50 (COMP), the signal ADAPT-1 being coupled to a non-inverting input and the signal ADAPT-2 to an inverting input. The signal SD at the output of gate 50 thus is in the high state during each period for a duration corresponding to the (set) phase shift between the signals ADAPT-1 and ADAPT-2.

To obtain information relative to the duration in the high state of the signal SD, a counter provides, after counting, a number which is an image of this duration.

This counter operates over several consecutive periods of the signal SD. To form this counter, clock input CLK is coupled to the input of a second phase-locked loop PLL2 having a frequency multiplication coefficient, nPLL2, which is different from but which may be close to multiplication coefficient nPLL1 of phase-locked loop PLL1. As an example, if clock signal CLK has a frequency on the order of a few MHz, phase-locked loops PLL1 and PLL2 may have multiplication coefficients such as 65 and 66. Other values may of course be used.

The output signal of phase-locked loop PLL2 is coupled to a frequency dividing circuit of coefficient M, the output signal of divider M defining the period during which the counter operates before a reset. The counting period should be sufficient to obtain reliable information at the counter output. The counting period should correspond at least to the lowest common multiple between the periods of the output signals of loop PLL1 and of loop PLL2.

The output of phase-locked loop PLL2 is coupled to the control input (on the rising edge) of two D flip-flops, 52 and 54. The output of divider M is coupled to the main input of a first D flip-flop 52, the Q output of flip-flop 52 being coupled to the main input of flip-flop 54.

A three-input AND gate 56 receives, on its inputs signal SD, the output of flip-flop 52, and the output of flip-flop 54. The output of gate 56 forms the activation signal of a counter COUNT 58. Counter 58 is synchronized on the rising edges of the output signal of the phase-locked loop PLL2. A two-input AND gate 60 receives the output of the flip-flop 54 on a non-inverting input and the output of flip-flop 52 on an inverting input, the output of gate 60 forming a signal for resetting (RST) the counter 58.

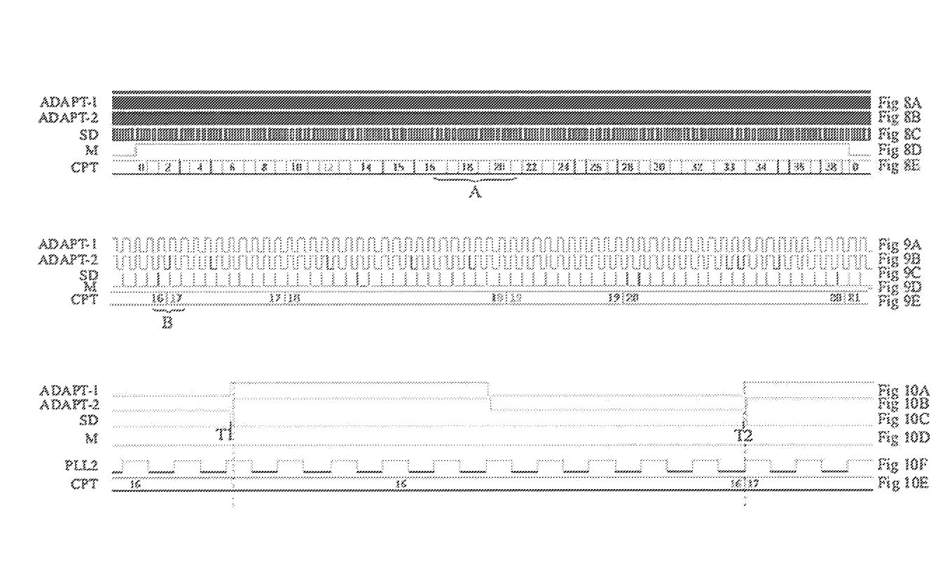

Counter 58 operates as follows. On each rising edge of the output signal of phase-locked loop PLL2, if the output of gate 56 is in the high state, that is, if the signal SD is in the high state and that one is in a counting phase (output signal of divider M in the high state), the counter increments. Due to the frequency difference of the output signals of phase-locked loops PLL1 and PLL2, the counter only increments a small number of times in a counting cycle, as will be seen in the timing diagrams of FIGS. 8A to 8E, 9A to 9E, and 10A to 10F. The number stored at the end of a counting cycle of the counter can be associated with a duration in the high state of the signal SD, and thus with a distance to the object.

FIGS. 8A to 8E, 9A to 9E, and 10A to 10F are timing diagrams illustrating the operation of the device of FIG. 11.

More specifically, the timing diagrams of FIGS. 8A to 8E illustrate a full counting cycle, FIGS. 9A to 9E are an enlargement of FIGS. 8A to 8E (portion A) over a few increments of counter 58, and FIGS. 10A to 10F illustrate the detail of an incrementing of counter 58 (portion B of FIGS. 9A to 9E).

The timing diagrams of FIGS. 8A to 8E, of FIGS. 9A to 9E, and of FIGS. 10A to 10E respectively illustrate the signal ADAPT-1, the signal ADAPT-2, the signal SD, the output signal of divider M, and the output of counter 58. The timing diagram of FIG. 10F further illustrates the output signal of loop PLL2.

As can be seen in these different timing diagrams, the counter is reset after M periods of the output signal of loop PLL2. The enlargements of FIGS. 10A to 10F show two pulses on the signal SD, one implying an increment of the counter, the other implying none.

At a time T1, a pulse on the signal SD appears, but no rising edge of the output signal of phase-locked loop PLL2 occurs during this pulse, which does not modify the counter state. At a time T2, a second pulse on the signal SD appears, and a rising edge of the output signal of phase-locked loop PLL2 occurs during this pulse, which increments the counter.

Due to the frequency difference between the output signals of loops PLL1 and PLL2, the rising edges of the output signal of loop PLL2, over a counting duration, occur at different times of the period of the signal SD. Thus, on a counting cycle, the longer the duration of the pulse on the signal SD, the more the counter increments. The value on counter 58 at the end of each counting cycle thus provides, by means of a block 62 (DISTANCE) for reading the value on the counter at the end of the cycle, a very accurate value of the distance to the object. The device of FIG. 11 may obtain very fine time accuracy by using clock signals at reasonable frequencies for an integrated circuit implementation, for example smaller than 1 GHz.

It should be noted that several counting cycles may be provided for a same distance to the object, with the possibility of then calculating an average to determine the a more accurate possible distance to the object.

In some embodiments, the signal SD may be shifted by a few periods of the output signal of block PLL1, with respect to the beginning of a period of the output signal of divider N, to make sure that all switching to the high state of the signal SD are effectively counted by the counter. The duration of the pulses on the signal SD may also be artificially increased for a better reading of the on-state duration of this signal, the value stored on the counter at the end of the counting cycle being accordingly adapted.

Specific embodiments have been described. Various alterations, modifications, and improvements will readily occur to those skilled in the art. In particular, embodiments are not limited to an association of ADLLs coupled to SPADs and to a system for determining the on-state duration such as that in FIG. 11.

Indeed, the above-described ADLLs may for example be coupled to other types of light sensors than SPADs, where the signals originating from these sensors are in the form of events occurring with the reception of light pulses. For example, rapid charge transfer photodiodes, which alternately transfer the photo generated charges onto two read nodes during a cycle, may be used. The amount of charges on each node in each cycle provides information relative to the distance to the object.

In the case of such diodes, the signal exhibiting detectable events considered to implement the method described herein will originate from the signal on each of the read nodes, the time of occurrence of said events being associated with the amount of light on each node. Circuitry configured to generate these events from the signal on the two read nodes may be provided.

In some embodiments, to determine the duration of a signal which is an image of the phase shift between two signals output by ADLLs, other devices than that described in relation with FIG. 11 may be used.

It should be appreciated that in some embodiments, different types of DLL may be used.

In some embodiments, the DLL s may be omitted and optionally replaced by any other suitable circuitry.

As shown in FIG. 12, an OR tree is provided for each array. The OR tree function is to allow the outputs of the respective phase shaper to be output in turn to the respective DLL. The OR tree can be regarded as functionally equivalent to a single OR gate with a separate input from each of the pulse shaping circuitry. With this arrangement, the same DLL circuitry may be used by two or more or all of the pulse shaping circuitry. In some embodiments, separate DLL circuitry may be provided for each pulse shaper. It should be appreciated that the outputs of the reference array and the measuring array may be controlled so that there is correspondence between the corresponding outputs of the measuring array 1 and the reference array 2. In other words, each SPAD of the measuring array has a respective corresponding SPAD in the reference array.

Some embodiments may use other sensors, instead of SPADs. These sensors may be integrating elements, rapid charge transfer photodiodes or any other suitable device which generates events on reception of the light information.

It should be appreciated that the above described arrangements may be implemented at least partially by an integrated circuit, a chip set, one or more dies packaged together or in different packages, discrete circuitry or any combination of these options.

It should be appreciated, that an application of some embodiments in a ranging device has been described. However, it should be appreciated that this only one example of an application of some embodiments. Other embodiments may be used with any other application of a SPAD or SPAD array or any other suitable photo sensitive device or photo sensitive device array.

It should be appreciated that the DLL arrangement shown is by way of example and can be replaced by any other suitable DLL arrangement.

It should be appreciated that the one or more DLLs may be replaced by any other suitable circuitry for providing a measure such as a count rate. For example a counter based architecture or a sigma delta converter may be used in some embodiments.

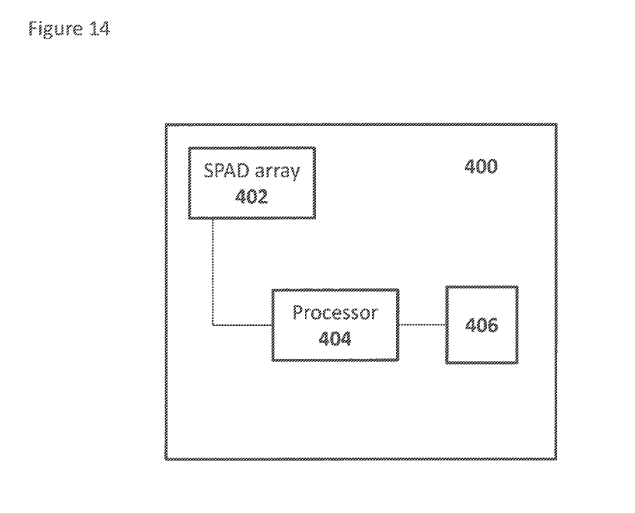

Some embodiments may be provided in a device 400 such as shown in FIG. 14. The device 400 may comprise any one of the SPAD or the like arrangements as previously described and referenced 402. An output from the SPAD arrangement may be provided to a processor 404. Based on the output provided by the processor an information or control signal may be output to function block 406. The function block may be a controller which is configured to cause one or more actions in response to detecting a presence of an object. The function block may be a display which is configured to display a measurement result.

It should be appreciated that the device may be any suitable device. By way of example only and without limitation, that device may be a mobile telephone, smart phone, tablet, computer, measuring device, switch controller such as for a light, controlling a water supply such as in a tap or toilet, door controller, distance sensor, impact controller, or any other suitable device.

Various embodiments with different variations have been described here above. It should be noted that those skilled in the art may combine various elements of these various embodiments and variations.

Such alterations, modifications, and improvements are intended to be part of this disclosure, and are intended to be within the scope of the present invention. Accordingly, the foregoing description is by way of example only and is not intended to be limiting. The present invention is limited only as defined in the following claims and the equivalents thereto.

What is claimed is:

1. An apparatus, comprising:
an array of photon sensitive devices, each photon sensitive device configured to be provided with a voltage when in use;
a digital counter configured to receive output from the array of photon sensitive devices; and
a controller configured to control a voltage source to apply at least two calibration voltages to the photon sensitive devices of the array in a calibration mode and further configured to determine said voltage to be provided by the voltage source in a normal mode of operation by:
receiving output counter values from the digital counter for each of the at least two calibration voltages during calibration mode; and
using the received counter values to determine the voltage to be provided by the voltage source in the normal mode of operation.

2. The apparatus as claimed in claim 1, wherein said controller is configured to cause the apparatus to be in said calibration mode at regular intervals.

3. The apparatus as claimed in claim 1, wherein said controller is configured to cause the apparatus to be in said calibration mode in response to one or more conditions being satisfied.

4. The apparatus as claimed in claim 1, wherein said controller is configured to control said voltage source to apply a first calibration voltage followed by at least one successive calibration voltage, the or each successive calibration voltage being decreased.

5. The apparatus as claimed in claim 1, wherein said controller is configured to control said voltage source to apply a first calibration voltage followed by at least one successive calibration voltage, the or each successive calibration voltage being increased.

6. The apparatus as claimed in claim 1, wherein said controller is configured to control said voltage source to apply a first calibration voltage followed by at least one successive calibration voltage, and wherein said first calibration voltage is selected to be one of a voltage below a breakdown voltage of the photon sensitive device and a voltage which causes the photon sensitive device to be in a state of breakdown.

7. The apparatus as claimed in claim 1, wherein said controller is configured to control said voltage source to apply a first calibration voltage followed by at least one successive calibration voltage, and wherein said successive calibration voltages are applied until the photon sensitive device operates as required in the normal mode of operation.

8. The apparatus as claimed in claim 1, wherein an offset is applied to a calibration voltage which is determined to allow operation of the photon sensitive device in the normal mode of operation.

9. The apparatus as claimed in claim 1, comprising a light source, said light source being controlled by said controller and being configured to be activated in said calibration mode.

10. The apparatus as claimed in claim 9, wherein the photon sensitive device is configured to be shielded from light other than said light source, when said apparatus is in the calibration mode.

11. The apparatus as claimed in claim 1, further comprising an additional photon sensitive device, said photon sensitive device being used in said calibration mode and said additional photon sensitive device being used in said normal mode of operation, said determined voltage being applied to said additional photon sensitive device in said normal mode of operation.

12. The apparatus as claimed in claim 1, wherein the photon sensitive device comprises a single photon avalanche diode.

13. The apparatus as claimed in claim 1, comprising said voltage source, wherein said voltage source comprises a charge pump.

14. The apparatus as claimed in claim 1, wherein the digital counter comprises counting circuitry configured to provide a count on activation of the photon sensitive device, said counting circuitry providing count information to said controller.

15. The apparatus of claim 1 provided in the form of an integrated circuit.

16. A method, comprising:
controlling a voltage source to apply at least two calibration voltages to a photon sensitive device in a calibration mode;
counting in a counter coupled to an output of the photon sensitive device counter values for each of the at least two calibration voltages; and
determining a voltage to be provided by the voltage source in a normal mode of operation, wherein determining comprises:
receiving counter values output from the counter for each of the at least two calibration voltages; and
using the received counter values to determine the voltage to be provided by the voltage source in the normal mode of operation.

17. The method as claimed in claim 16, comprising performing said calibration mode at regular intervals.

18. The method as claimed in claim 16, comprising performing said calibration mode in response to one or more conditions being satisfied.

19. The method as claimed in claim 16, comprising controlling said voltage source to apply a first calibration voltage followed by at least one successive calibration voltage, the or each successive calibration voltage being decreased.

20. The method as claimed in claim 16, comprising controlling said voltage source to apply a first calibration voltage followed by at least one successive calibration voltage, the or each successive calibration voltage being increased.

21. The method as claimed in claim 16, comprising controlling said voltage source to apply a first calibration voltage followed by at least one successive calibration voltage, wherein said first calibration voltage is one of a voltage below a breakdown voltage of the photon sensitive device and a voltage which causes the photon sensitive device to be in a state of breakdown.

22. The method as claimed in claim 16, comprising controlling said voltage source to apply a first calibration voltage followed by at least one successive calibration voltage, and applying successive calibration voltages until the photon sensitive device operates as required in the normal mode of operation.

23. The method as claimed in claim 16, comprising applying an offset to a calibration voltage which is determined to allow operation of the photon sensitive device in the normal mode of operation.

24. The method as claimed in claim 16, comprising controlling a light source to be activated in said calibration mode.

25. The method as claimed in claim 16, wherein the photon sensitive device comprises a single photon avalanche diode.

26. The method as claimed in claim 16, wherein said voltage source comprises a charge pump.

27. The method as claimed in claim 16, wherein the counter values comprise an activation count of the photon sensitive device.
